(19) United States
(12) Patent Application Publication
(10) Pub. No.: US 2019/0165013 A1
(43) Pub. Date: May 30, 2019

(54) PACKAGE FOR IRIS RECOGNITION IMAGING MODULE AND MANUFACTURING METHOD THEREOF

(71) Applicant: China Wafer Level CSP Co., Ltd., Suzhou (CN)

(72) Inventors: Zhiqi Wang, Suzhou (CN); Mingxuan Wu, Suzhou (CN)

(73) Assignee: China Wafer Level CSP Co., Ltd., Suzhou (CN)

(21) Appl. No.: 16/202,144

(22) Filed: Nov. 28, 2018

(30) Foreign Application Priority Data
Nov. 30, 2017 (CN) 201711237255.X
Nov. 30, 2017 (CN) 201721644311.7

(51) Int. Cl. H01L 27/146; G06K 9/00; H04N 5/33

(52) U.S. Cl. CPC H01L 27/14601; H01L 27/14683; H04N 5/33; G06K 9/00281; G06K 9/00597

(57) ABSTRACT

A package for an iris recognition imaging module and a method for manufacturing a package for an iris recognition imaging module are provided. An image sensing chip is bonded with a substrate having a window, with an image sensing region of the image sensing chip being facing towards the window and covered by the window. The image sensing chip is electrically connected with a wiring line. The substrate is provided with an infrared light-emitting diode (LED), and a shielding member for preventing at least a part of infrared light emitted by the infrared LED from entering the image sensing region. With the shielding member, the amount of infrared light of the infrared LED entering the image sensing chip can be reduced while providing compensation light, thereby reducing interference to the iris imaging and improving the accuracy of the iris recognition.

The present application claims priorities to Chinese Patent Application No. 201711237255.X, titled “PACKAGE FOR IRIS RECOGNITION IMAGING MODULE AND MANUFACTURING METHOD THEREOF”, filed on Nov. 30, 2017 with the Chinese Patent Office and Chinese Patent Application No. 201721644311.7, titled “PACKAGE FOR IRIS RECOGNITION IMAGING MODULE”, filed on Nov. 30, 2017 with the Chinese Patent Office, both of which are incorporated herein by reference in their entireties.

### FIELD

The present disclosure relates to the technical field of semiconductors, and in particular to a package for an iris recognition imaging module and a method for manufacturing a package for an iris recognition imaging module.

### BACKGROUND

With the continuous development of technology, people pay more attention to the personal identity recognition and the personal information security. In the iris recognition technology, the identity recognition is performed by using irises of eyes. The irises are unique to everyone, cannot be copied, and cannot be stolen, thus have good security when being applied to the identity recognition.

A package for an iris recognition imaging module mainly includes an image sensing chip, a circuit substrate and a cover plate. The circuit substrate and the image sensing chip are connected together by a flip-chip process. The cover plate is arranged above the image sensing chip to filter out other light entering the image sensing chip than the infrared light. At present, an infrared light-emitting diode (LED) is generally arranged near the cover plate to provide infrared compensation for eyes, so as to improve the quality of the iris imaging. However, the infrared light emitted by the infrared LED may enter the image sensing chip through the cover plate while providing the compensation light, which causes interference to the iris imaging because the infrared light is non-imaging light.

### SUMMARY

In view of this, a package for an iris recognition imaging module and a method for manufacturing a package for an iris recognition imaging module are provided in a first aspect of the present disclosure, to eliminate infrared interference caused by an infrared LED.

A package for an iris recognition imaging module is provided according to an embodiment of the present disclosure, which includes: a substrate including a first surface and a second surface opposite to each other, where the substrate is provided with a window and a wiring line;

an image sensing chip bonded on the first surface, including an image sensing region, where the image sensing region faces towards the window and is covered by the window, and the image sensing chip is electrically connected with the wiring line;

an infrared LED bonded on the second surface, where the infrared LED is electrically connected with the wiring line; and

a shielding member fixed on the second surface, where the shielding member is configured to prevent at least a part of infrared light emitted by the infrared LED from entering the image sensing region.

In an embodiment, the shielding member includes at least a shielding wall arranged at a side of the infrared LED adjacent to the image sensing region.

In an embodiment, the shielding wall is made of resin or photosensitive ink.

In an embodiment, the shielding member is a shielding plate.

In an embodiment, the shielding plate is a straight plate or an arc-shaped plate.

In an embodiment, the shielding member is a first hollow box, two ends of the first hollow box are open, the infrared LED is arranged in a cavity of the first hollow box, and a side of the first hollow box adjacent to the image sensing region serves as the shielding wall.

In an embodiment, the shielding member includes a second hollow box, two ends of the second hollow box are open, the second hollow box surrounds the window, the infrared LED is arranged outside the second hollow box, and a side of the second hollow box adjacent to the infrared LED serves as the shielding wall.

In an embodiment, the shielding member further includes a third hollow box, two ends of the third hollow box are open, and the third hollow box surrounds the second hollow box and the infrared LED.

In an embodiment, the hollow box has a round or square cross-section.

In an embodiment, the package further includes: a cover plate fixed on the second surface and covering the image sensing region, where the cover plate transmits only infrared light.

In an embodiment, the cover plate is made of Infra-Red (IR) glass.

In an embodiment, the cover plate is fixed on the substrate or the shielding member.

In an embodiment, the package further includes: a support member fixed on the second surface, with the cover plate being fixed on the support member.

In an embodiment, the package further includes: contact terminals fixed on the first surface. The contact terminals are electrically connected with the wiring line.

In an embodiment, the contact terminals are pins, contact pads or solder balls.

In an embodiment, a surface of the image sensing chip facing towards the window is provided with first contact pads, and the first contact pads surround the image sensing region and are electrically connected with the wiring line.

In an embodiment, the first surface of the substrate is provided with second contact pads in a one-to-one correspondence with the first contact pads, and each of the second contact pads is electrically connected with one of the first contact pads.

In an embodiment, the package further includes: a sealant arranged between the image sensing chip and the substrate.

In an embodiment, the substrate is a printed circuit board (PCB) substrate, a glass substrate, a plastic substrate or a semiconductor substrate.

In an embodiment, the second surface of the substrate is provided with third contact pads, and the third contact pads are electrically connected with the infrared LED.

In an embodiment, the infrared LED is a sapphire infrared LED device.

In an embodiment, the infrared LED includes an light emission direction control device configured to control the infrared LED to emit light in a direction having a preset angle with a first direction perpendicular to the substrate.

A method for manufacturing a package for an iris recognition imaging module is further provided according to an embodiment of the present disclosure, which includes:

providing a base, where the base includes multiple substrates arranged in an array, a cutting trench is formed between adjacent substrates among the multiple substrates, each of the multiple substrates includes a window region and a wiring region surrounding the window region, the wiring region is provided with a wiring line, and each of the multiple substrates has a first surface and a second surface opposite to each other;

forming a window in the window region of each of the multiple substrates;

bonding an image sensing chip on the first surface of each of the multiple substrates, to electrically connect the image sensing chip with the wiring line, where the image sensing chip includes an image sensing region, the image sensing region faces towards the window and is covered by the window;

bonding an infrared LED on the second surface of each of the multiple substrates, where the infrared LED is electrically connected with the wiring line;

fixing a shielding member on the second surface of each of the multiple substrates, where the shielding member is configured to prevent at least a part of infrared light emitted by the infrared LED from entering the image sensing region; and

cutting the base along the cutting trench.

In an embodiment, after forming a window in the window region of each of the multiple substrates, the method further includes: fixing a cover plate on the second surface of each of the multiple substrates, where the cover plate covers the window and transmits only infrared light.

In an embodiment, after fixing a shielding member on the second surface of each of the multiple substrates, the method further includes: fixing a cover plate on the shielding member, where the cover plate covers the image sensing region and transmits only infrared light.

In an embodiment, after forming a window in the window region of each of the multiple substrates, the method further includes: forming a support member on the second surface of each of the multiple substrates; and fixing a cover plate on the support member, where the cover plate covers the image sensing region and transmits only infrared light.

In an embodiment, the method further includes: forming contact terminals on the wiring region of the first surface of each of the multiple substrates, where the contact terminals are electrically connected with the wiring line.

In the package and the method for an iris recognition imaging module according to the embodiments of the present disclosure, the image sensing chip is bonded with the substrate having a window, with the image sensing region of the image sensing chip being facing towards the window and covered by the window. The image sensing chip is electrically connected with the wiring line. The substrate is provided with the infrared LED, and the shielding member for preventing at least a part of infrared light emitted by the infrared LED from entering the image sensing region. With the shielding member, the amount of infrared light of the infrared LED entering the image sensing chip can be reduced while providing compensation light, thereby reducing interference to the iris imaging and improving the accuracy of the iris recognition.

### BRIEF DESCRIPTION OF THE DRAWINGS

FIGS. 1 to 18 show schematic diagrams of a package for an iris recognition imaging module according to an embodiment of the present disclosure;

FIG. 19 shows a flowchart of a method for manufacturing a package for an iris recognition imaging module according to an embodiment of the present disclosure; and

FIGS. 20 to 30 are respectively schematic diagrams of intermediate structures formed in the method for manufacturing a package for an iris recognition imaging module according the embodiment of the present disclosure.

### DETAILED DESCRIPTION OF EMBODIMENTS

Specific details are described in the following description, so that the present disclosure can be fully understood. The present disclosure may be implemented in other manners than those described herein, and those skilled in the art can make modifications without departing from the scope of the present disclosure. Therefore, the present disclosure is not limited to the specific embodiments described below.

In addition, the present disclosure is described in detail in conjunction with the drawings. In the detailed description of the present disclosure, a sectional view showing a device structure may be partially enlarged with a non-normal scale, and is only exemplary, which does not limit the protection scope of the present disclosure. Moreover, three-dimensional sizes including a length, a width and a depth should be considered during actual fabricating. In addition, the statement “a first structure is above a second structure” described herein should be understood that, the first structure is in direct contact with the second structure, or the first structure is not in direct contact with the second structure, with another structure being formed between the first structure and the second structure.

In order to make the above objects, features and advantages of the present disclosure more apparent and easier to be understood, embodiments of the present disclosure are illustrated in detail in conjunction with the drawings hereinafter.

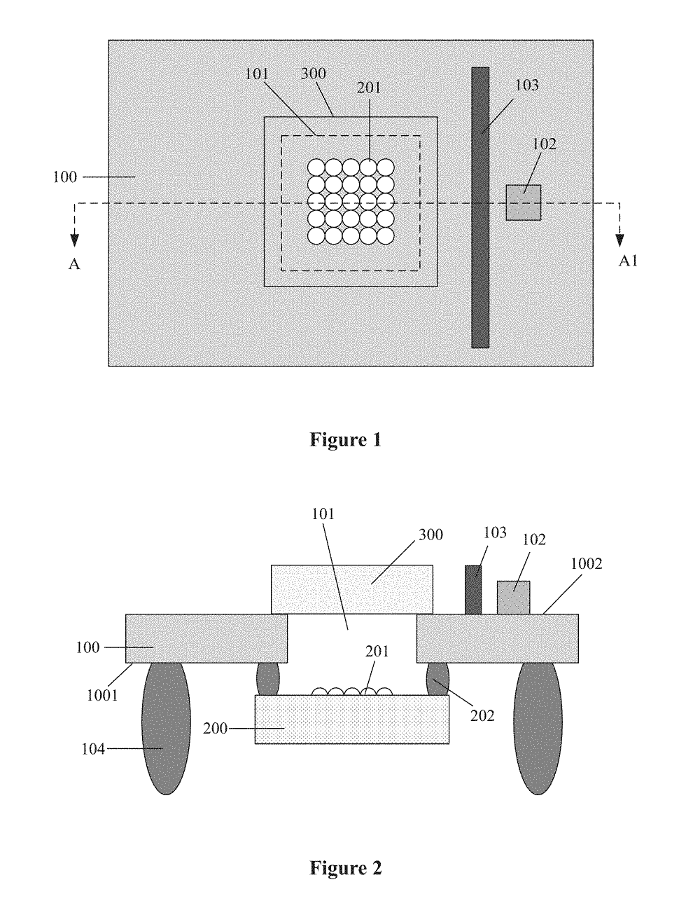

Reference is made to FIG. 1 and FIG. 2. FIG. 1 is a top view of a package for an iris recognition imaging module according to an embodiment of the present disclosure. FIG. 2 is a sectional view of the package for an iris recognition imaging module taken along a line AA1 in FIG. 1. The package for an iris recognition imaging module according to the embodiment of the present disclosure includes: a substrate 100 including a first surface 1001 and a second surface 1002 opposite to each other, an image sensing chip 200 bonded on the first surface 1001, an infrared LED 102 bonded on the second surface 1002, and a shielding member 103 fixed on the second surface 1002. The image sensing chip 200 includes an image sensing region 201.

The substrate 100 is provided with a window 101. A position and a size of the window 101 may be adjusted according to actual situations. The substrate 100 includes the first surface 1001 and the second surface 1002 opposite to each other. The first surface 1001 of the substrate 100 serves as an image side and faces towards the image sensing chip 200. The second surface 1002 of the substrate 100 serves as an object side and faces towards human eyes in the iris imaging.

The substrate 100 may be a PCB substrate, a glass substrate, a plastic substrate or a semiconductor substrate. In a case that the substrate 100 is a semiconductor substrate, the semiconductor substrate may be a silicon substrate, a germanium substrate, a silicon germanium substrate, or other substrates made of appropriate semiconductor materials. The substrate 100 is provided with a wiring line (which is not shown in the figure).

The image sensing chip 200 is bonded on the first surface 1001 of the substrate 100. The image sensing chip 200 includes the image sensing region 201. The image sensing region 201 faces towards the window 101 of the substrate 100 and is covered by the window 101, so that light can enter the image sensing region 201 via the window 101. For ease of wiring, the image sensing region 201 may be generally located at the middle of the image sensing chip 200. The window 101 of the substrate 100 exposes the image sensing region 201. In actual applications, the light enters the image sensing region 201 via the window, and the image sensing region 201 senses external light and generates an electrical signal.

The image sensing region 201 is provided with at least an image sensor unit, and may further be provided with an association circuit connected with the image sensor unit, such as a drive unit (which is not shown in the figure) for driving a chip, an acquiring unit (which is not shown in the figure) for acquiring a photosensitive region current and a processing unit (which is not shown in the figure) for processing the photosensitive region current. Practically, the image sensing chip 200 may further be provided with other components according to design requirements, which is not described in detail hereinafter.

Further, in the embodiment of the present disclosure, first contact pads (which are not shown in the figure) may be arranged on a surface of the image sensing chip 200 facing towards the window 101. The first contact pads surround the image sensing region 201. In the case that the image sensing region 201 is located at the middle of the image sensing chip 200, the first contact pads may be located on the periphery of the image sensing region 201 and at the edge of the image sensing chip 200 in a rectangular pattern. In addition, positions of the image sensing region 201 and the first contact pads, and the number of the first contact pads may be adjusted according to different requirements.

The first contact pads serve as an input/output port between a component in the image sensing region 201 and an external circuit. The first contact pads are electrically connected with the wiring line, to transmit the electrical signal from the image sensing region 201 to the external circuit via the wiring line. The first contact pads may be made of conductive materials, for example, metal materials such as Al, Au and Cu.

In the embodiment of the present disclosure, second contact pads (which are not shown in the figure) in a one-to-one correspondence with the first contact pads may be arranged on the first surface 1001 of the substrate 100. Each of the first contact pads is electrically connected with one of the second contact pads, for example, via a solder ball 202, a conductive adhesive or other metal connection materials. In addition, the second contact pads are electrically connected with the wiring line.

In an embodiment of the present disclosure, a sealant such as polymer resin may be formed outside the first contact pad and second contact pad electrically connected with each other. The sealant is formed between the substrate 100 and the image sensing chip 200 surrounding the image sensing region 201, to prevent foreign materials from entering the image sensing region 201. In addition, the sealant may prevent the image sensing chip 200 from falling off, which is not described in detail herein.

Moreover, contact terminals 104 may be fixed on the first surface 1001 of the substrate 100. In an embodiment, the contact terminals 104 may be symmetrically arranged at two sides of the image sensing chip 200. The contact terminals 104 are electrically connected with the wiring line of the substrate 100, to transmit the electrical signal generated by the image sensing region 201 to the external circuit. The contact terminals 104 may be pins, contact pads, solder balls, or the like.

In a case that the contact terminals 104 are contact pads or solder balls, the contact terminals 104 may be secured with the external circuit together by welding or by using a conductive adhesive in the package for an iris recognition imaging module, to electrically connect the wiring line with the external circuit.

In a case that the contact terminals 104 are pins, the external circuit has jacks. The contact terminals 104 are pins matching with the jacks. Each of the pins is electrically connected with the external circuit via one of the jacks. In this case, the wiring line is electrically connected with the external circuit by plugging the pin with the jack.

The infrared LED 102 is bonded on the second surface 1002 of the substrate 100. The infrared LED 102 is electrically connected with the wiring line of the substrate 100 and is connected to the external circuit via the wiring line and the contact terminals 104. The infrared LED 102 is used for infrared scanning or infrared light compensation, so as to improve the quality of the iris imaging. In the case that the package for an iris recognition imaging module according to the embodiment of the present disclosure includes the infrared LED 102, the external circuit may include an LED control circuit configured to control an operation state of the infrared LED 102.

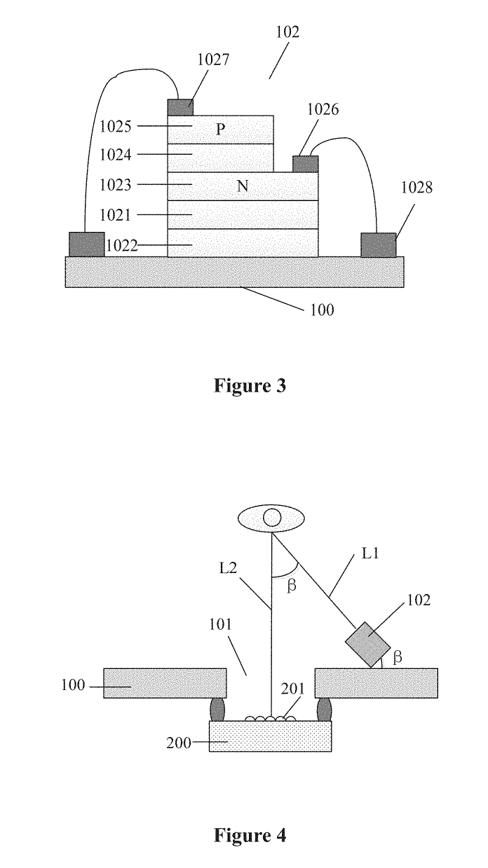

As shown in FIG. 3, the infrared LED 102 in the embodiment of the present disclosure is a sapphire infrared LED device, i.e., an infrared LED device formed on a sapphire substrate. The infrared LED 102 may include: a sapphire substrate 1021, an N-type semiconductor layer 1023, a light-emitting function layer 1024, a P-type semiconductor layer 1025, and a second electrode 1027. The sapphire substrate 1021 is fixed on the substrate 100, and a surface of the sapphire substrate 1021 facing towards the substrate 100 is provided with a reflection layer 1022. The N-type semiconductor layer 1023 is located at a side of the sapphire substrate 1021 facing away from the substrate 100. The light-emitting function layer 1024 is located at a side of the N-type semiconductor layer 1023 facing away from the sapphire substrate 1021. The P-type semiconductor layer 1025 is located at a side of the light-emitting function layer 1024 facing away from the N-type semiconductor layer 1023. The second electrode 1027 is located at a side of the P-type semiconductor layer 1025 facing away from the light-emitting function layer 1024. The second electrode 1027 exposes a part of the P-type semiconductor layer 1025, to emit infrared light. The light-emitting function layer 1024 exposes a part of the N-type semiconductor layer. A first electrode 1026 is provided on a surface of the exposed part of the N-type semiconductor layer.

As shown in FIG. 3, the infrared LED 102 is arranged on the second surface of the substrate 100 in a face-up manner. The infrared LED 102 may be electrically connected with the substrate, to provide an electrical signal for the infrared LED 102 by the substrate 100. In some embodiments, third contact pads 1028 may be arranged on the second surface of the substrate 100. The third contact pads 1028 are electrically connected with the wiring line. The infrared LED 102 is electrically connected with the third contact pads. As an example, the first electrode 1026 and the second electrode 1027 are respectively electrically connected with different third contact pads 1028 via wires. As another example, the first electrode 1026 and the second electrode 1027 may be respectively electrically connected with different third contact pads 1028 by an anisotropic conductive adhesive (which is not shown in the figure), and an insulation layer may be provided between a side wall of the infrared LED and the anisotropic conductive adhesive. As another example, the first electrode 1026 and the second electrode 1027 may be respectively electrically connected with different third contact pads 1028 by forming a conductive thin film by an evaporation process, and an insulation layer may be provided between the conductive thin film and a side wall of the infrared LED. The structure of the infrared LED and the electrical connection between the infrared LED and the substrate herein are only exemplary, and the present disclosure is not limited thereto. In other examples, other structures and connections may be further adopted. For example, the infrared LED 102 may be arranged on the second surface of the substrate 100 in a face-down manner.

When an operating voltage is applied between the first electrode 1026 and the second electrode 1027, the light-emitting function layer 1024 emits infrared light. The N-type semiconductor layer 1023 may be an N-type doped GaN layer. The P-type semiconductor layer 1025 may be a P-type doped GaN layer. By arranging the reflection layer 1022 below the sapphire substrate 1021, the infrared light emitting efficiency can be improved.

In order to ensure that the light emitted by the infrared LED 102 is incident to the image sensing chip 200 via the window 101 of the substrate 100, the infrared LED 102 is provided with a light emission direction control device configured to control the infrared LED 102 to emit light in a direction having a preset angle with a first direction perpendicular to the substrate 100, so that the light emitted by the infrared LED 102 can illuminate to human eyes, thereby improving the quality of the iris recognition imaging.

Reference is made to FIG. 4, which is a schematic structural diagram of a package for an iris recognition imaging module according to another embodiment of the present disclosure. The first direction is perpendicular to the substrate 100, such as a straight line L2 perpendicular to the substrate 100 at the center of the image sensing region 201. An angle between a light emission direction of the infrared LED 102 and L2 is indicated by β. In an embodiment, the preset angle β is greater than 0° and not greater than 10°. The preset angle may be set based on positions of the infrared LED 102, the image sensing region 201 and the iris, so that much infrared light can be incident to the image sensing chip 200 via the window 101. For example, the preset angle may be 7°.

In order to form the preset angle β between the light emission direction of the infrared LED 102 and the first direction, a fixing device or an adhesive layer may be arranged between the infrared LED 102 and the substrate 100, to cause the infrared LED 102 to be inclined on the surface of the substrate 100, with the light exit opening being inclined towards the window 101 with an inclination angle β.

As shown in FIG. 2, a shielding member 103 is fixed on the second surface of the substrate 100. The shielding member 103 is configured to prevent at least a part of infrared light emitted by the infrared LED 102 from entering the image sensing region 201. The shielding member 103 may include at least a shielding wall arranged at a side of the infrared LED 102 adjacent to the image sensing region 201. The shielding wall may be made of resin, photosensitive ink, or other materials that can shield the infrared light.

A cover plate 300 is fixed on the second surface of the substrate 100 to cover the image sensing region 201, so as to protect the image sensing region 201. The cover plate 300 transmits only infrared light and filters out light of other wavebands, thereby improving the quality of the iris imaging. The cover plate 300 may be made of Infra-Red (IR) glass. For example, the cover plate 300 may be an infrared filter including a transparent glass substrate and an infrared light plating arranged at a side of the transparent glass substrate facing towards the image sensing region 201. The infrared light plating transmits the infrared light and filters out the visible light. In this way, the light of other wavebands may be filtered out by the cover plate 300, so as to not affect the iris imaging, thereby ensuring the quality of the iris imaging and improving the accuracy of the iris recognition. In actual applications, the infrared light plating may be arranged at the side of the transparent glass substrate facing towards the image sensing region 201, so as to not damage the infrared light plating due to the mechanical friction.

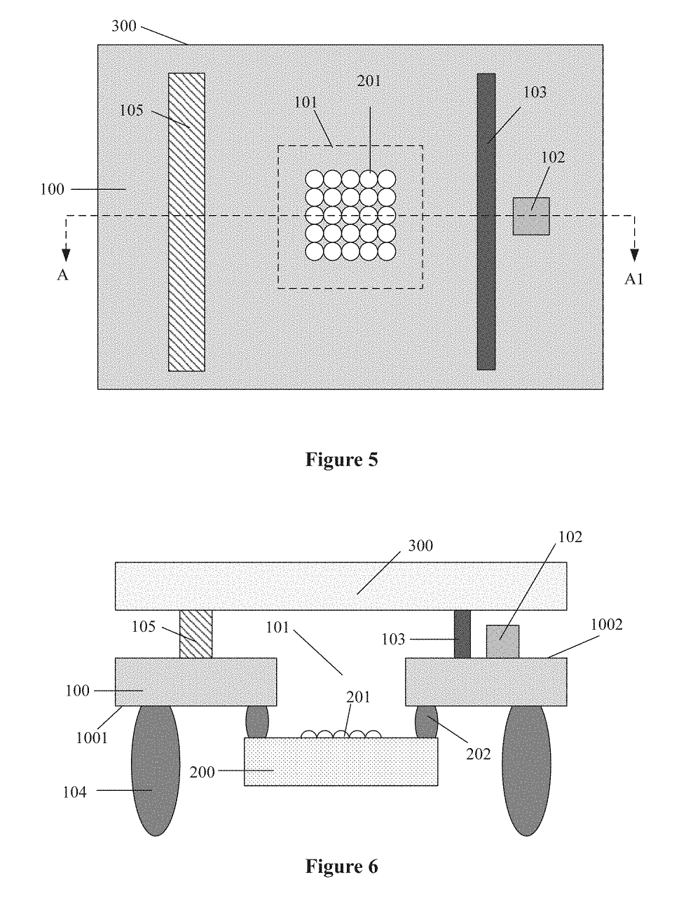

In an embodiment, as shown in FIG. 1, FIG. 2, FIG. 5 and FIG. 6, the shielding member 103 may be a shielding wall arranged at only a side of the image sensing region 201 adjacent to the infrared LED 102. The shielding wall may be a shielding plate such as a straight plate, an arc-shaped plate or other irregular shielding plates. The shielding plate may be higher or lower than the infrared LED 102. The shape of the shielding plate is not limited in the present disclosure, as long as the shielding plate can prevent a part of the infrared light from entering the image sensing region 201.

In this embodiment, as shown in FIG. 1 and FIG. 2, the cover plate 300 may be fixed on the substrate 100 and covers only the window 101, so as to protect the image sensing region 201. The cover plate may be square or round, which is not limited herein.

Alternatively, as shown in FIG. 5 and FIG. 6 which is a sectional view of a package for an iris recognition imaging module taken along a line AA1 in FIG. 5, the cover plate 300 may be fixed on the shielding wall. A support member 105 may be arranged on the second surface of the substrate 100 at one or more sides including no shielding wall, to support the cover plate 300. The support member 105 may be made of the same material as or different materials from the shielding wall. The cover plate 300 is fixed on both the shielding wall and the support member 105 or fixed on only the support member 105.

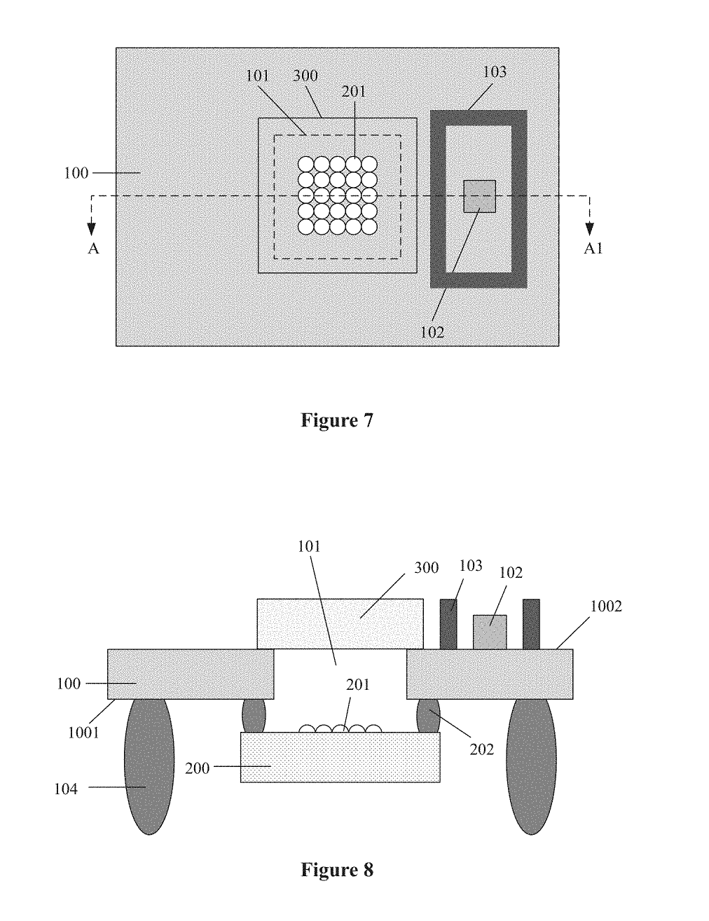

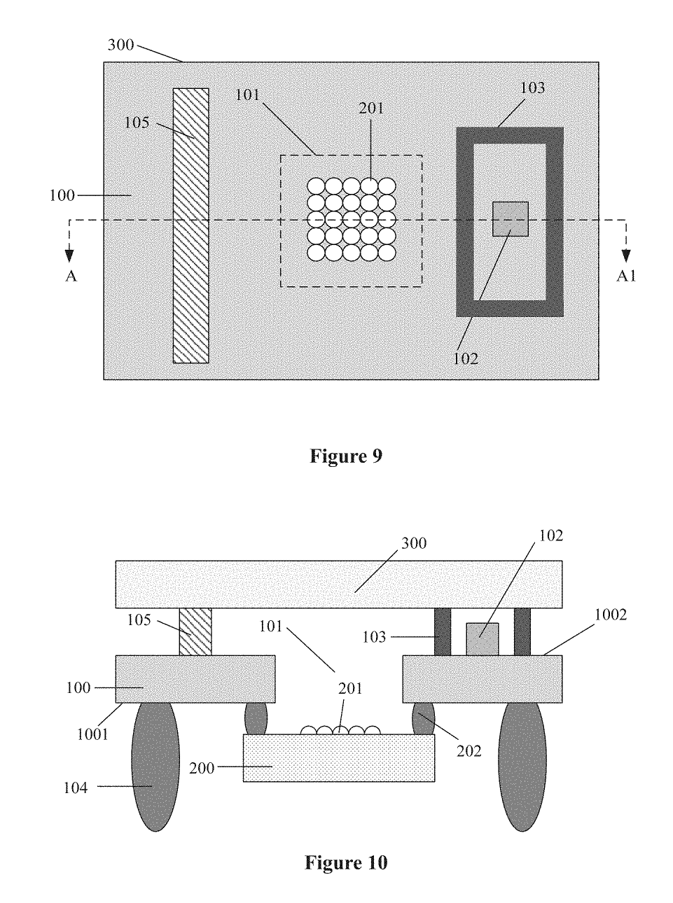

In an embodiment, as shown in FIG. 7, FIG. 8, FIG. 9 and FIG. 10, the shielding member 103 may be a first hollow box arranged on the periphery of the infrared LED 102. An upper end and a lower end of the first hollow box are open, and one of the two ends is fixed on the substrate. The infrared LED 102 is arranged in a cavity of the first hollow box. A side of the first hollow box adjacent to the image sensing region 201 serves as the shielding wall. A portion of the first hollow box away from the image sensing region 201 may be made of the same material as or different materials from the shielding wall. The shielding member 103 having the box structure not only prevents the light emitted by the infrared LED from entering the infrared sensing region, but also protects the infrared LED 102 from physical damages.

In this embodiment, as shown in FIG. 7 and FIG. 8 which is a sectional view of a package for an iris recognition imaging module taken along a line AA1 in FIG. 7, the cover plate 300 may be fixed on the substrate 100 and covers only the window 101.

The cover plate 300 may also be fixed on the first hollow box and covers the window 101, and further covers a part or all of the first hollow box, to fully protect the infrared LED 102. In an embodiment, as shown in FIG. 9 and FIG. 10 which is a sectional view of a package for an iris recognition imaging module taken along a line AA1 in FIG. 9, a support member 105 may be formed at one or more sides including no first hollow box, and the cover plate 300 may be fixed on both the support member 105 and the first hollow box or fixed on only the support member 105.

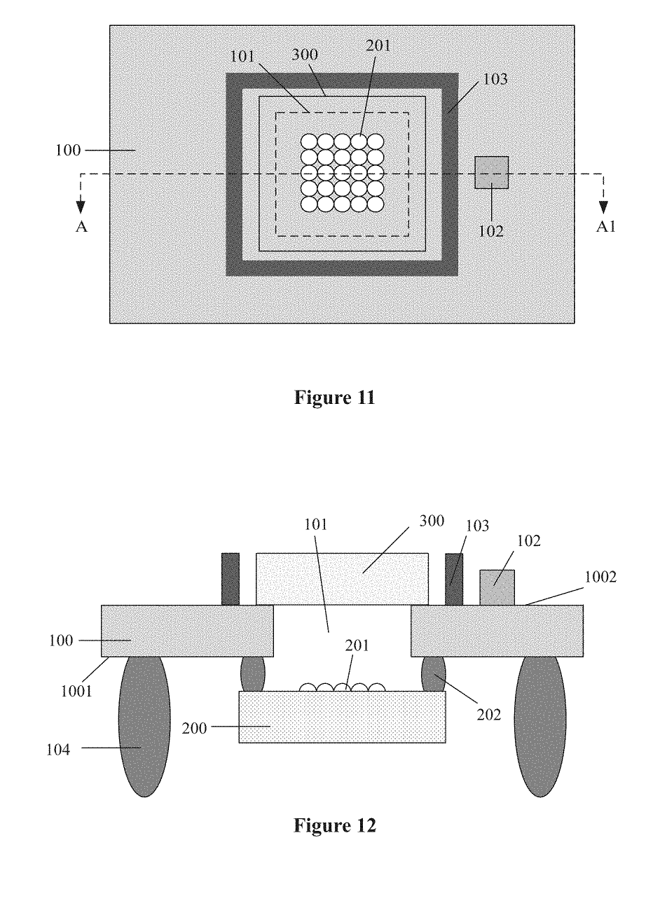

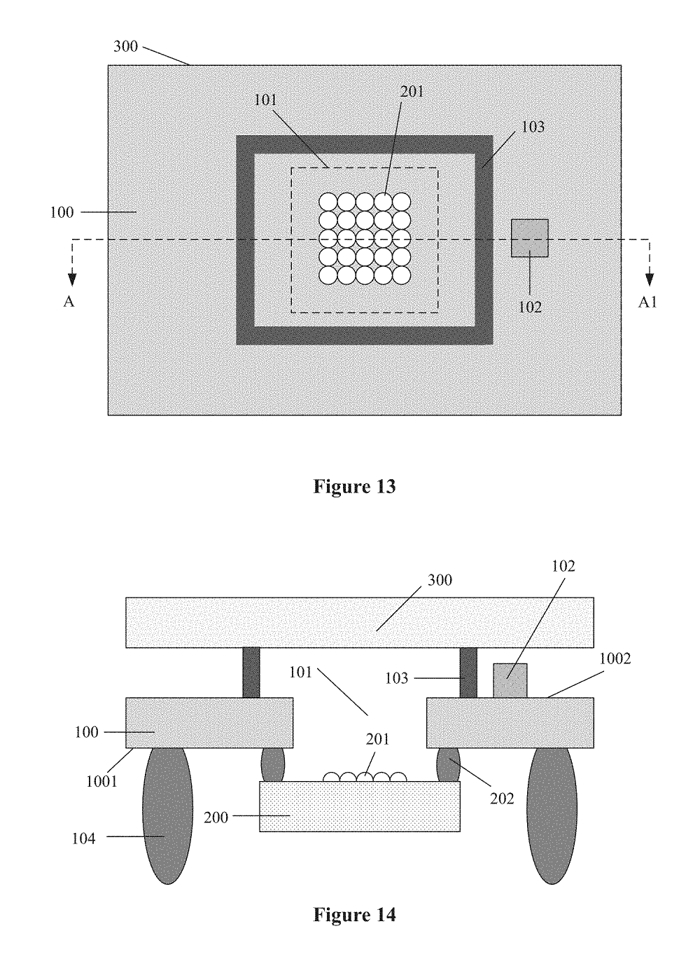

In an embodiment, as shown in FIG. 11, FIG. 12, FIG. 13 and FIG. 14, the shielding member 103 may be a second hollow box arranged on the periphery of the window 101. Two ends of the second hollow box are open, and one of the two ends is fixed on the substrate. The second hollow box surrounds the window 101. The infrared LED 102 is arranged outside the second hollow box. A side of the second hollow box adjacent to the infrared LED 102 serves as the shielding wall. A portion of the second hollow box other than the shielding wall may be made of the same material as or different materials from the shielding wall. The hollow box surrounding the window not only prevents the light emitted by the infrared LED from entering the infrared sensing region, but also protects the window region and the image sensing region.

In this embodiment, as shown in FIG. 11 and FIG. 12 which is a sectional view of a package for an iris recognition imaging module taken along a line AA1 in FIG. 11, the cover plate 300 may be fixed on the substrate 100. The cover plate 300 is located inside the second hollow box and covers only the window 101.

As shown in FIG. 13 and FIG. 14 which is a sectional view of a package for an iris recognition imaging module taken along a line AA1 in FIG. 13, the cover plate 300 may also be fixed on the second hollow box and covers both the window 101 and the second hollow box, and further extends to a position above the infrared LED, to protect the infrared LED, thereby improving the device integration level.

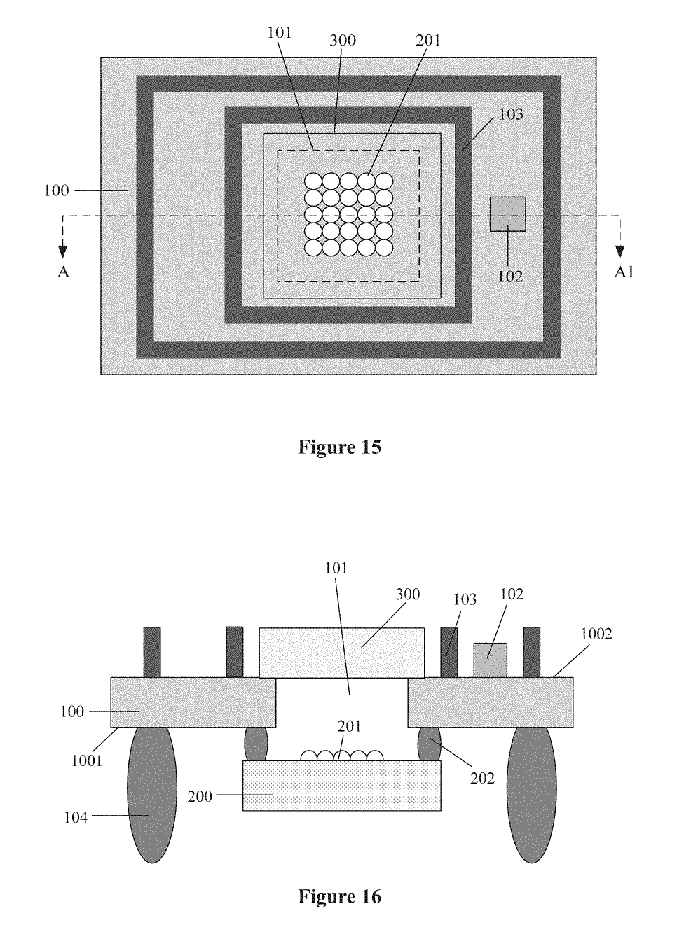

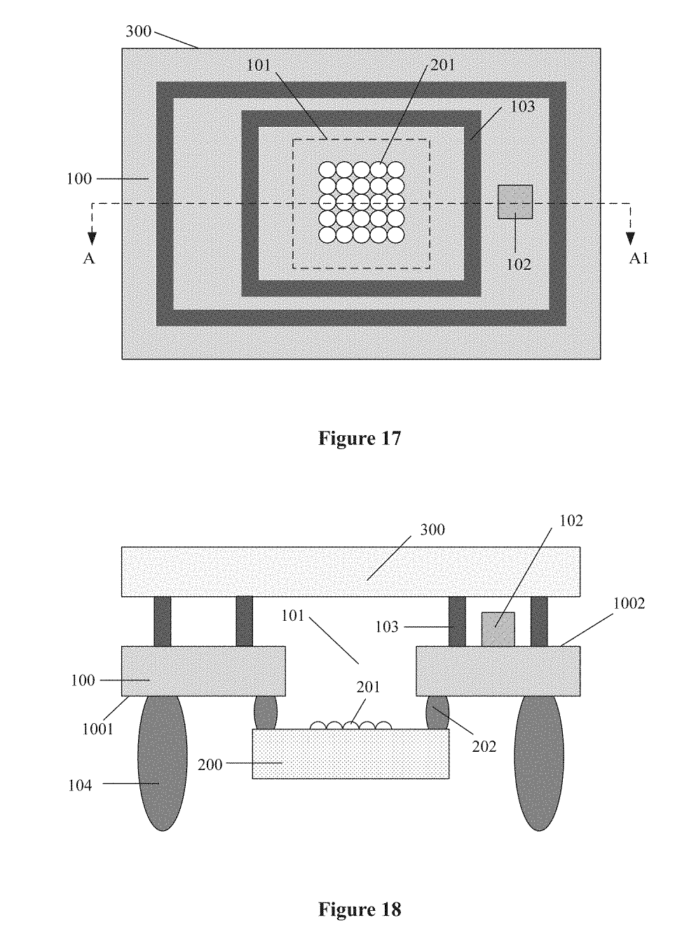

In an embodiment, as shown in FIG. 15, FIG. 16, FIG. 17 and FIG. 18, the shielding member 103 may include a second hollow box and a third hollow box which are nested. Two ends of the third hollow box and two ends of the second hollow box are open. The third hollow box surrounds the second hollow box and the infrared LED 102, to protect the infrared LED 102 well.

In this embodiment, as shown in FIG. 15 and FIG. 16 which is a sectional view of a package for an iris recognition imaging module taken along a line AA1 in FIG. 15, the cover plate 300 may be fixed on the substrate 100. The cover plate 300 is located inside the second hollow box and covers only the window 101.

As shown in FIG. 17 and FIG. 18 which is a sectional view of a package for an iris recognition imaging module taken along a line AA1 in FIG. 17, the cover plate 300 may also be fixed on the third hollow box and the second hollow box, and covers both the window 101 and the third hollow box, to protect both the infrared LED 102 and the image sensing region 201.

Each of the hollow box, the second hollow box and the third hollow box may has a square, round, polygonal or irregular cross-section. The square cross-section can be a true square cross-section or a rectangular cross-section. The hollow box may be higher or lower than the infrared LED, which is not limited herein.

In the package for an iris recognition imaging module according to the embodiment of the present disclosure, the image sensing chip is bonded with the substrate having a window, with the image sensing region of the image sensing chip being facing towards the window and covered by the window. The image sensing chip is electrically connected with the wiring line. The substrate is provided with the infrared LED, and the shielding member for preventing at least a part of infrared light emitted by the infrared LED from entering the image sensing region. With the shielding member, the amount of infrared light of the infrared LED entering the image sensing chip can be reduced while providing compensation light, thereby reducing interference to the iris imaging and improving the accuracy of the iris recognition.

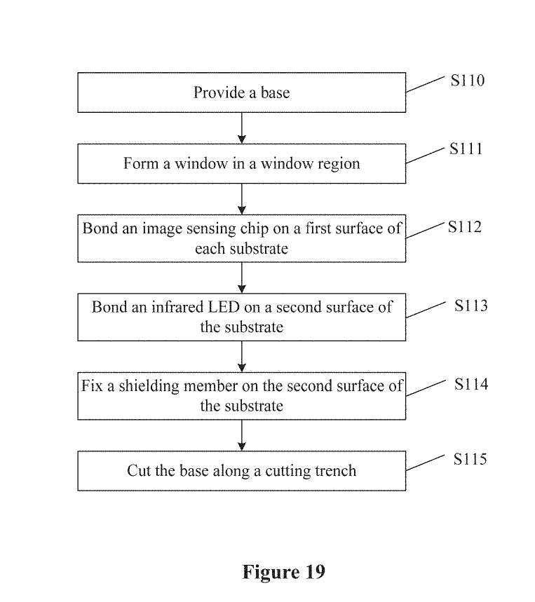

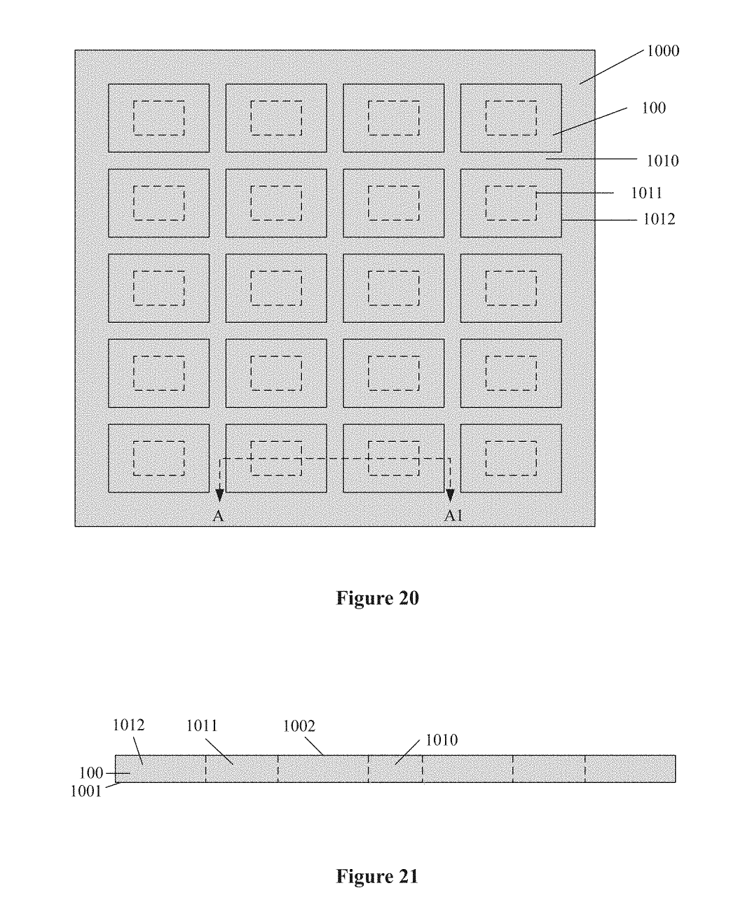

Based on the package for an iris recognition imaging module according to the above embodiment, a method for manufacturing a package for an iris recognition imaging module is further provided according to an embodiment of the present disclosure. FIG. 19 shows a flowchart of a method for manufacturing a package for an iris recognition imaging module according to an embodiment of the present disclosure. The method is illustrated with reference to FIGS. 20 to 30, which are sectional views of intermediate structures formed in the method for manufacturing a package for an iris recognition imaging module according to the embodiment of the present disclosure. The method includes the following steps S110 to S115.

In step S110, a base 1000 is provided.

The base 1000 includes multiple substrates 100 arranged in an array. A cutting trench 1010 is arranged between adjacent substrates 100. Each of the multiple substrates 100 includes a window region 1011 and a wiring region 1012 surrounding the window region 1011. The wiring region 1012 is provided with a wiring line. Each of the multiple substrates 100 has a first surface 1001 and a second surface 1002 opposite to each other. Reference is made to FIG. 20 and FIG. 21. FIG. 21 is a sectional view of a package for an iris recognition imaging module taken along a line AA1 in FIG. 20.

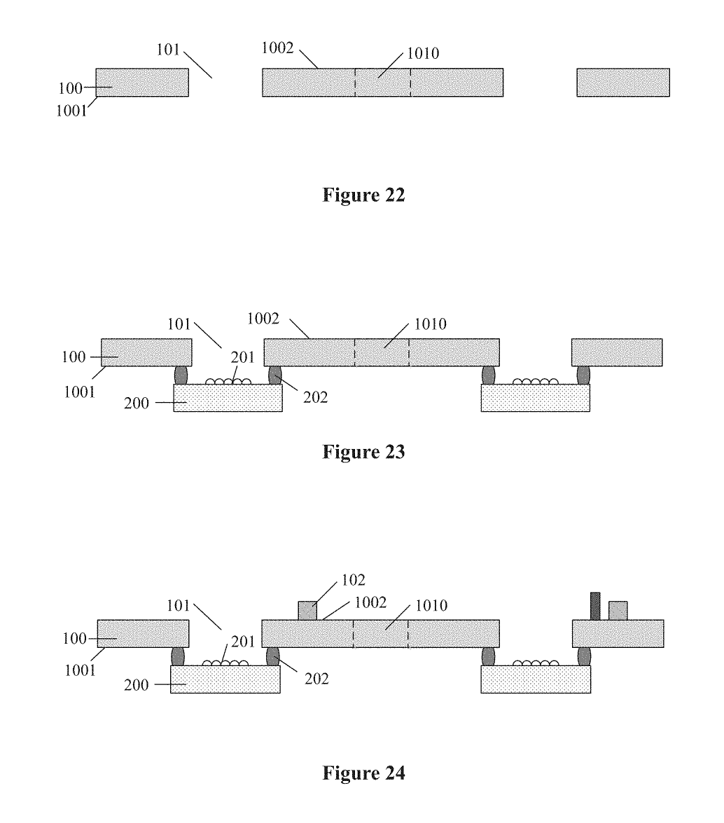

In step S111, as shown in FIG. 22, a window 101 is formed in the window region 1011.

One window 101 is formed in each window region 1011. A size of the window 101 is set based on a size of the to-be-bonded image sensing chip 200. The size of the window 101 may be less than or equal to the size of the window region 1011, which is not limited herein. In an embodiment, the window 101 is located in a central region of the window region 1011 corresponding to the window 101, and the center of the window 101 is the same as the center of the window region 1011. The window 101 may be formed by an etching process, a laser-drill process or a mechanical grinding process.

In step S112, an image sensing chip 200 is bonded on the first surface 1001 of each of the multiple substrates 100, to electrically connect the image sensing chip 200 with the wiring line.

The image sensing chip 200 includes an image sensing region 201. The image sensing region 201 faces towards the window 101 and is covered by the window 101, as shown in FIG. 23. Each of to-be-bonded image sensing chips 200 is provided with the image sensing region 201. After the to-be-bonded image sensing chips 200 are bonded, each window region 1011 is fixed with one image sensing chip 200, and each formed window 101 completely covers the image sensing region 201 corresponding to the window 101 in a direction perpendicular to the base 1000. In actual applications, the light enters the image sensing region 201 via the window 101, and the image sensing region 201 converts the sensed light into an electrical signal.

The image sensing chip 200 is bonded on the first surface of the substrate 100 by being electrically connected via contact pads. A surface of the image sensing chip 200 facing towards the window 101 may be provided with first contact pads (which are not shown in the figure). The first contact pads surround the image sensing region 201. The first surface 1001 of the substrate 100 may be provided with second contact pads in a one-to-one correspondence with the first contact pads. Each of the first contact pads is electrically connected with one of the second contact pads.

In an example, the first contact pad may be a gold bump. The first contact pad and the second contact pad may be electrically connected with each other by a thermal compression process or by using conductor materials such as a solder ball 202 or a conductive adhesive. The gold bump is applicable to a flip chip package technology. In the flip chip package technology, the image sensing chip 200 is inverted on the substrate 100 which may be a flexible substrate or a glass substrate, the gold bump may be directly bonded with the second contact pad on the substrate 200 by a thermal compression process, thereby achieving the electrical connection between the gold bump and the second contact pad. With the gold bump technology, the volume of the package for an iris recognition imaging module can be greatly reduced. In addition, the gold bump technology has advantages such as high density, low induction, low cost and good heat dissipation. The gold bump technology may be applied to the Chip On Glass (COG) and the Chip On Film (COF).

The image sensing chip 200 may be bonded on the first surface of the substrate 100 by a gold-silicon eutectic melting process, so that the image sensing chip 200 is fixed on the substrate 100. In this case, the image sensing chip 200 has a silicon base, and a surface of the window region 1011 facing towards the image sensing chip 200 is provided with a metal layer. The gold-silicon eutectic melting process may be performed at a set temperature and pressure, to fix the image sensing chip 200 on the substrate 100.

In step 113, as shown in FIG. 24, an infrared LED 102 is bonded on the second surface of the substrate 100. The infrared LED 102 is electrically connected with the wiring line.

In an embodiment, a fixing device or an adhesive layer may be arranged between the infrared LED 102 and the substrate 100, to fix the infrared LED 102 on the surface of the substrate 100.

The infrared LED 102 is used for infrared scanning or infrared light compensation, so as to improve the quality of the iris imaging. In an embodiment, the wiring region 1012 of the second surface of the substrate 100 is provided with third contact pads 1028, as shown in FIG. 3. The third contact pads 1028 are electrically connected with the wiring line. The infrared LED 102 is electrically connected with the third contact pads. The first electrode 1026 and the second electrode 1027 of the infrared LED 102 may be respectively electrically connected with different third contact pads 1028 via wires, by using a conductive adhesive or a conductive thin film. The detail description thereof may refer to the description of the package for an iris recognition imaging module provided in the present disclosure, which is not repeated herein.

When an operating voltage is applied between the first electrode 1026 and the second electrode 1027, the light-emitting function layer 1024 emits infrared light. In order to ensure that the light emitted by the infrared LED 102 is incident to the image sensing chip 200 via the window 101 of the substrate 100, a light emission direction control device is provided to control a light emission direction of the infrared LED 102, so that the light emitted by the infrared LED 102 can illuminate to human eyes, thereby improving the quality of the iris recognition imaging. In an embodiment, the infrared LED 102 may be inclined on the surface of the substrate 100, with the light exit opening being inclined towards the window 101 with an inclination angle β.

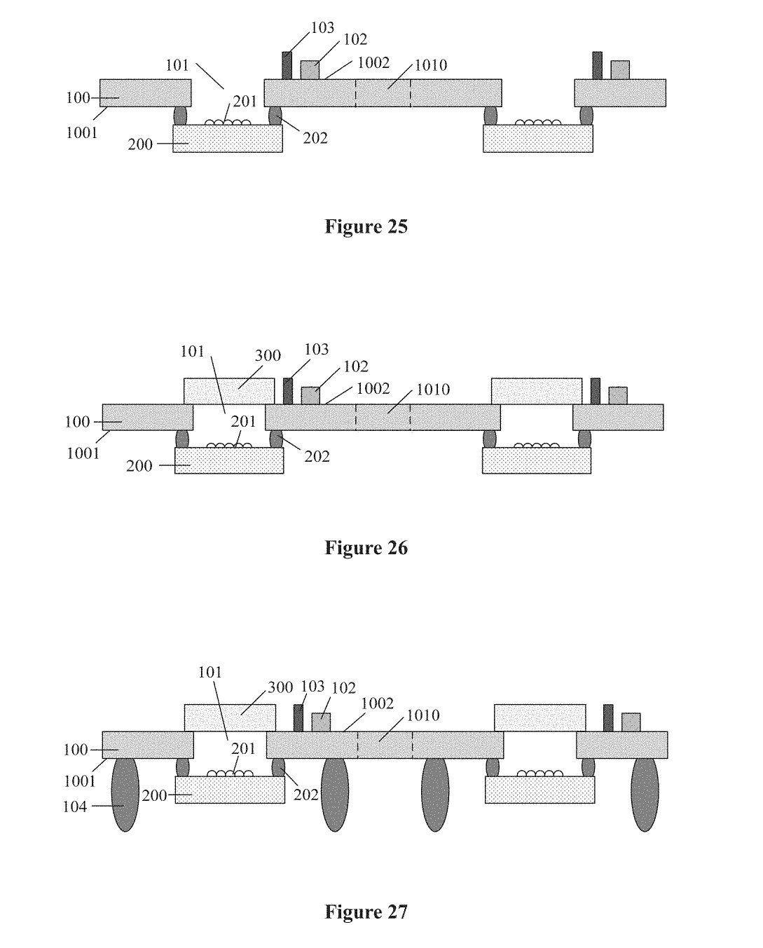

In step S114, as shown in FIG. 25, a shielding member 103 is fixed on the second surface of the substrate 100. The shielding member 103 is used to prevent at least a part of infrared light emitted by the infrared LED 102 from entering the image sensing region 201.

The shielding member 103 may include at least a shielding wall arranged at a side of the infrared LED 102 adjacent to the image sensing region 201. The shielding wall may be made of resin, photosensitive ink, or other materials that can shield the infrared light. In an embodiment, a fixing device or an adhesive layer may be between the shielding member 103 and the substrate 100, to fix the shielding member 103 on the surface of the substrate 100. In the embodiment of the present disclosure, the shielding member 103 may be the shielding plate arranged at a side of the image sensing region 201 adjacent to the infrared LED 102, the first hollow box, the second hollow box or the third hollow box, the detail description thereof may refer to the description of the package for an iris recognition imaging module. In the following, the method is described by taking the shielding plate as the shielding member 103.

A shielding plate is arranged on the side of the image sensing region 201 adjacent to the infrared LED 102, as shown in FIG. 25. The shielding plate may be a straight plate or an arc-shaped plate. The shielding plate can prevent a part of the infrared light from entering the image sending region 201, thereby reducing interference from the infrared light and improving the quality of the iris imaging.

In an embodiment, step S114 may further include: fixing a cover plate 300 on the second surface of the substrate 100, with the cover plate 300 covering only the window 101, as shown in FIG. 26. In this way, the image sensing region 201 is protected. The cover plate 300 may be fixed on the substrate 100 by using a fixing device or an adhesive layer. The cover plate 300 may have a square shape or other shapes, which is not limited herein.

The cover plate 300 transmits only infrared light and filters out light of other wavebands, thereby improving the quality of the iris imaging. The cover plate 300 may be made of IR glass. For example, the cover plate 300 may be an infrared filter in which an infrared light plating is formed on a transparent glass substrate by a fitting process or a vacuum plating process. In the process of fixing the cover plate 300 on the second surface 1002 of the substrate 100, the infrared light plating may be formed at a side of the transparent glass substrate facing towards the image sensing region 201, to avoid the damage on the infrared light plating due to the mechanical friction. In addition, step S114 may further include forming contact terminals 104 on the wiring region of the first surface 1011, where the contact terminals 104 are electrically connected with the wiring line, as shown in FIG. 27. The contact terminals 104 may be formed by referring to the description of the iris recognition imaging module structure according to the embodiment of the present disclosure, which is not repeated herein.

In another embodiment, after the shielding member 103 is formed, a cover plate 300 may be arranged on the shielding member 103. In the case that the shielding member 103 is a shielding plate, the cover plate 300 is arranged on the shielding plate. For example, the cover plate 300 may be fixed by using a fixing device or an adhesive layer. In an embodiment, the shielding plate is arc-shaped, which facilitates fixing of the cover plate 300.

The contact terminals 104 are formed on the wiring region 1012 of the first surface 1001, and are electrically connected with the wiring line.

In another embodiment, a support member 105 may be arranged on the substrate 100 at one or more sides including no shielding wall. The support member 105 may be made of the same material as or different materials from the shielding wall.

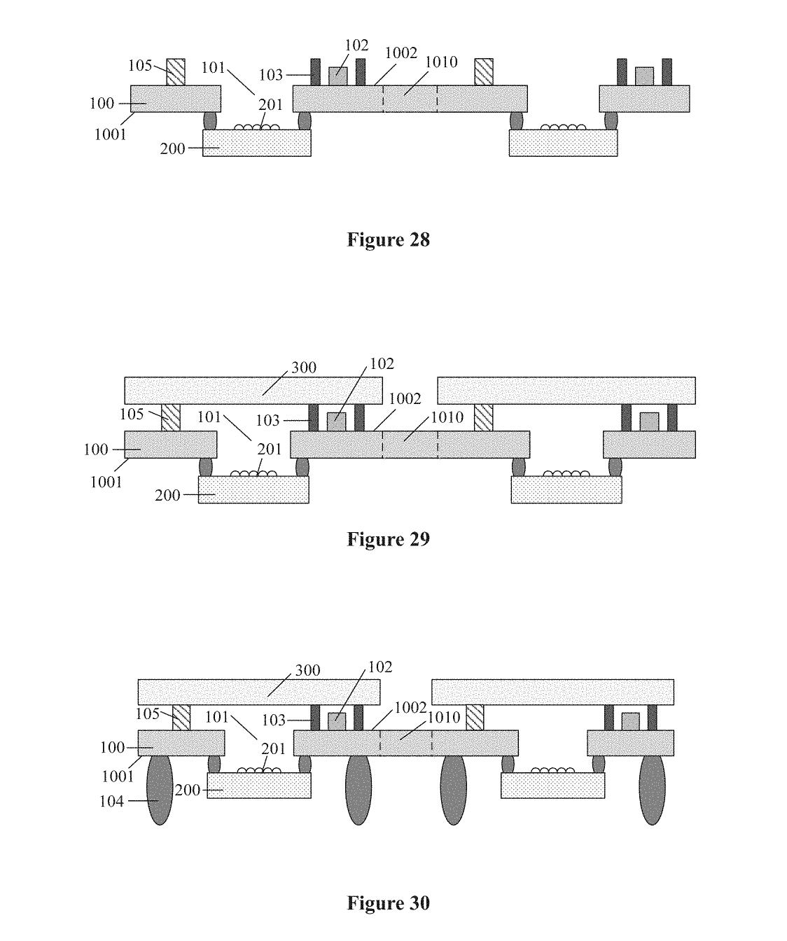

The support member 105 may be also formed at the side having the shielding wall, such as a support member 105 arranged at a side of the infrared LED 102 away from the shielding wall and made of the same material as the shielding wall, as shown in FIG. 28. The support member 105 may be connected with the shielding wall, for example, to form the first hollow box as shown in FIG. 9, or the support member 105 may be a separate component.

The cover plate 300 is fixed on both the support member 105 and the shielding wall and covers the image sensing region 201 and the infrared LED 102, to protect both the image sensing region 201 and the infrared LED 102, as shown in FIG. 29.

The contact terminals 104 are formed on the wiring region 1012 of the first surface 1001, and are electrically connected with the wiring line, as shown in FIG. 30.

Step S114 may be performed before step S113 or after step S113, or may be performed together with step S113. It should be noted that, in the embodiment in which the cover plate 300 covers only the window 101, the infrared LED 102, the shielding member 103, the cover plate 300 and the contact terminal 104 may be fixed on the substrate 100 in an arbitrary order. In the embodiment in which the cover plate 300 is fixed on the shielding member 103, the shielding member 103 is fixed before the cover plate 300 is fixed, while the infrared LED 102, and the contact terminal 104 may be fixed on the substrate 100 in an arbitrary order. In the embodiment in which the cover plate 300 is fixed on the support member 105, the cover plate 300 is fixed after the infrared LED 102, the shielding member 103 and the support member 105 are fixed, while the infrared LED 102, the shielding member 103 and the support member 105 may be fixed in an arbitrary order, and the contact terminal 104 may be fixed at any time instant.

In other embodiments of the present disclosure, step S112 may be performed after step S113 or after step S114, or may be performed together with step S113 or S114, which is not limited in the present disclosure.

In step S115, the base is cut along the cutting trench 1010.

After the cutting is performed, the base 1000 is divided into multiple substrates 100 in a one-to-one correspondence with the image sensing chips 200.

In the method for manufacturing a package for an iris recognition imaging module according to the embodiment of the present disclosure, the image sensing chip is bonded with the substrate having a window, with the image sensing region of the image sensing chip being facing towards the window and covered by the window. The image sensing chip is electrically connected with the wiring line. The substrate is provided with the infrared LED, and the shielding member for preventing at least a part of infrared light emitted by the infrared LED from entering the image sensing region. With the shielding member, the amount of infrared light of the infrared LED entering the image sensing chip can be reduced while providing compensation light, thereby reducing interference to the iris imaging and improving the accuracy of the iris recognition.

The present disclosure is disclosed above, which is not limited thereto. Those skilled in the art may make various changes and modifications to the technical solutions of the present disclosure without departing from the spirit and scope of the present disclosure. Therefore, the protection scope of the present disclosure is defined by the appended claims.

1. A package for an iris recognition imaging module, comprising:
a substrate comprising a first surface and a second surface opposite to each other, wherein the substrate is provided with a window and a wiring line;
an image sensing chip bonded on the first surface, comprising an image sensing region, wherein the image sensing region faces towards the window and is covered by the window, and the image sensing chip is electrically connected with the wiring line;
an infrared light-emitting diode (LED) bonded on the second surface, wherein the infrared LED is electrically connected with the wiring line; and
a shielding member fixed on the second surface, wherein the shielding member is configured to prevent at least a part of infrared light emitted by the infrared LED from entering the image sensing region.

2. The package according to claim 1, wherein the shielding member comprises at least a shielding wall arranged at a side of the infrared LED adjacent to the image sensing region.

3. The package according to claim 2, wherein the shielding wall is made of resin or photosensitive ink.

4. The package according to claim 2, wherein the shielding member is a shielding plate, and the shielding plate is a straight plate or an arc-shaped plate.

5. The package according to claim 2, wherein the shielding member is a first hollow box, two ends of the first hollow box are open, the infrared LED is arranged in a cavity of the first hollow box, and a side of the first hollow box adjacent to the image sensing region serves as the shielding wall.

6. The package according to claim 2, wherein the shielding member comprises a second hollow box, two ends of the second hollow box are open, the second hollow box surrounds the window, the infrared LED is arranged outside the second hollow box, and a side of the second hollow box adjacent to the infrared LED serves as the shielding wall.

7. The package according to claim 6, wherein the shielding member further comprises a third hollow box, two ends of the third hollow box are open, and the third hollow box surrounds the second hollow box and the infrared LED.

8. The package according to claim 2, further comprising:
a cover plate fixed on the second surface and covering the image sensing region, wherein the cover plate transmits only infrared light, and the cover plate is made of Infra-Red (IR) glass.

9. The package according to claim 8, wherein the cover plate is fixed on the substrate or the shielding member.

10. The package according to claim 8, further comprising:
a support member fixed on the second surface, with the cover plate being fixed on the support member.

11. The package according to claim 1, further comprising:
contact terminals fixed on the first surface, wherein the contact terminals are electrically connected with the wiring line.

12. The package according to claim 1, wherein a surface of the image sensing chip facing towards the window is provided with first contact pads, and the first contact pads surround the image sensing region and are electrically connected with the wiring line.

13. The package according to claim 12, wherein the first surface of the substrate is provided with second contact pads in a one-to-one correspondence with the first contact pads, and each of the second contact pads is electrically connected with one of the first contact pads.

14. The package according to claim 1, further comprising:
a sealant arranged between the image sensing chip and the substrate.

15. The package according to claim 1, wherein the second surface of the substrate is provided with third contact pads, and the third contact pads are electrically connected with the infrared LED.

16. A method for manufacturing a package for an iris recognition imaging module, comprising:
providing a base, wherein the base comprises a plurality of substrates arranged in an array, a cutting trench is formed between adjacent substrates among the plurality of substrates, each of the plurality of substrates comprises a window region and a wiring region surrounding the window region, the wiring region is provided with a wiring line, and each of the plurality of substrates has a first surface and a second surface opposite to each other;
forming a window in the window region of each of the plurality of substrates;
bonding an image sensing chip on the first surface of each of the plurality of substrates, to electrically connect the image sensing chip with the wiring line, wherein the image sensing chip comprises an image sensing region, the image sensing region faces towards the window and is covered by the window;
bonding an infrared light-emitting diode (LED) on the second surface of each of the plurality of substrates, wherein the infrared LED is electrically connected with the wiring line;
fixing a shielding member on the second surface of each of the plurality of substrates, wherein the shielding member is configured to prevent at least a part of infrared light emitted by the infrared LED from entering the image sensing region; and
cutting the base along the cutting trench.

17. The method according to claim 16, wherein after forming a window in the window region of each of the plurality of substrates, the method further comprises:
fixing a cover plate on the second surface of each of the plurality of substrates, wherein the cover plate covers the window and transmits only infrared light.

18. The method according to claim 16, wherein after fixing a shielding member on the second surface of each of the plurality of substrates, the method further comprises:
fixing a cover plate on the shielding member, wherein the cover plate covers the image sensing region and transmits only infrared light.

19. The method according to claim 16, wherein after forming a window in the window region of each of the plurality of substrates, the method further comprises:
forming a support member on the second surface of each of the plurality of substrates; and
fixing a cover plate on the support member, wherein the cover plate covers the image sensing region and transmits only infrared light.

20. The method according to claim 16, further comprising:
forming contact terminals on the wiring region of the first surface of each of the plurality of substrates, wherein the contact terminals are electrically connected with the wiring line.
